(19) United States
(12) Patent Application Publication
(10) Pub. No.: US 2015/0191818 A1
(43) Pub. Date: Jul. 9, 2015

(54) VERTICAL FURNACE

(71) Applicant: SAMSUNG ELECTRONICS CO., LTD., Suwon-si (KR)

(72) Inventors: Sang-Ryol YANG, Suwon-si (KR); Young-Sub YOU, Osan-si (KR); Jin-Hwa HEO, Suwon-si (KR)

(73) Assignee: SAMSUNG ELECTRONICS CO., LTD., Suwon-si (KR)

(21) Appl. No.: 14/561,706

(22) Filed: Dec. 5, 2014

(30) Foreign Application Priority Data
Jan. 8, 2014 (KR) 10-2014-0002320

(51) Int. Cl. C23C 16/44; C23C 16/455

(52) U.S. Cl. CPC C23C 16/4412; C23C 16/455

(57) ABSTRACT

A vertical furnace is provided. The vertical furnace includes a chamber having a process space configured to receive substrates, a first exhaust passageway in fluidic communication with the process space, and a second exhaust passageway in fluidic communication with the process space and isolated from the first exhaust passageway; an injecting unit configured to inject a reaction gas into the process space; and an exhausting unit in fluidic communication with the first exhaust passageway and the second exhaust passageway and configured to provide the first exhaust passageway and the second exhaust passageway with an exhausting pressure.

CROSS-RELATED APPLICATION

This application claims priority from Korean Patent Application No. 2014-2320, filed on Jan. 8, 2014 in the Korean Intellectual Property Office, the contents of which are herein incorporated by reference in their entirety.

### BACKGROUND

1. Field

Apparatuses and articles of manufacture consistent with exemplary embodiments relate to a vertical furnace and, more particularly, to a vertical furnace configured to process a plurality of semiconductor substrates.

2. Description of the Related Art

Generally, a vertical furnace is used to process semiconductor substrates. The vertical furnace produces various exhaust gasses during the processing of the semiconductor substrates.

In related art vertical furnaces, an exhaust pressure is often not uniformly supplied to a process space within the vertical furnace. Moreover, since reaction gases may not be uniformly applied to the semiconductor substrates, layers on the semiconductor substrates may have bad thickness uniformity.

### SUMMARY

Exemplary embodiments provide a vertical furnace that may be capable of providing a uniform exhausting pressure to a process space.

According to an aspect of an exemplary embodiment, there is provided a vertical furnace including: a chamber comprising a process space configured to receive substrates, a first exhaust passageway in fluidic communication with the process space, and a second exhaust passageway in fluidic communication with the process space and isolated from the first exhaust passageway; an injecting unit configured to inject a reaction gas into the process space; and an exhausting unit in fluidic communication with the first exhaust passageway and the second exhaust passageway and configured to provide the first exhaust passageway and the second exhaust passageway with an exhausting pressure.

The first exhaust passageway may have a volume larger than a volume of the second exhaust passageway.

A distance from a first connection between the first exhaust passageway and the process space to the exhausting unit may be longer than a distance from a second connection between the second exhaust passageway and the process space to the exhausting unit.

The chamber may include an outer tube; an inner tube arranged within the outer tube to define the process space inside the inner tube; and a first partition connected between the inner tube and the outer tube to partition a space between the outer tube and the inner tube into the first exhaust passageway and the second exhaust passageway, and to isolate the first exhaust passageway from the second exhaust passageway.

The first partition may include a first horizontal wall connected between an outer surface of the inner tube and an inner surface of the outer tube; and a first vertical wall that extends from each end of the first horizontal wall to lower ends of the inner tube and the outer tube, respectively.

The inner tube may have a first slit that connects the first exhaust passageway and the process space; and a second slit that connects the second exhaust passageway and the process space.

The first slit may have an area larger than an area of the second slit.

The chamber may further include a third exhaust passageway in fluidic communication with the process space and isolated from the first exhaust passageway and from the second exhaust passageway.

The chamber may further include a third exhaust passageway in fluidic communication with the process space and isolated from the first exhaust passageway and from the second exhaust passageway, and wherein the third exhaust passageway has a volume smaller than the volume of the second exhaust passageway.

The chamber may include an outer tube; an inner tube arranged within the outer tube to define the process space inside the inner tube; a first partition connected between the inner tube and the outer tube to partition a space between the outer tube and the inner tube into the first exhaust passageway and the second exhaust passageway, and to isolate the first exhaust passageway from the second exhaust passageway; and a second partition connected between the inner tube and the outer tube to partition the space between the outer tube and the inner tube into the second exhaust passageway and the third exhaust passageway, and to isolate the third exhaust passageway from the second exhaust passageway.

The inner tube may have a first slit that connects the first exhaust passageway and the process space; a second slit that connects the second exhaust passageway and the process space; and a third slit that connects the third exhaust passageway and the process space.

The third slit may have an area smaller than areas of the first slit and the second slit.

The vertical furnace may further include a mount block arranged under the chamber, the mount block having a main exhaust passageway that connects the first exhaust passageway, the second exhaust passageway, and the exhausting unit.

According to an aspect of another exemplary embodiment, there is provided a vertical furnace including a chamber having a process space configured to receive substrates; an injecting unit configured to inject a reaction gas into the process space; first and second exhaust ducts connected to respective openings in a side surface of the chamber so as to be in fluidic communication with the process space, the first and second exhaust ducts having different diameters; and an exhausting unit in fluidic communication with the first and second exhaust ducts and configured to provide the first and second exhaust ducts with an exhausting pressure.

A distance from the first exhaust duct to the exhausting unit may be longer than a distance from the second exhaust duct to the exhausting unit, and the first exhaust duct has a diameter larger than a diameter of the second exhaust duct.

The first exhaust passageway may include an opening formed in a side surface of the chamber, and the second exhaust passageway may comprise an opening formed in the side surface of the chamber, and the vertical furnace may further comprise first and second exhaust ducts in fluidic communication with the first exhaust passageway and the second exhaust passageway, respectively, the first and second exhaust ducts having different diameters; and an exhausting unit in fluidic communication with the first and second exhaust ducts and configured to provide the first and second exhaust ducts with an exhausting pressure.

According to an aspect of another exemplary embodiment, there is provided a vertical furnace including a chamber including a process space configured to receive substrates, the chamber extending in a vertical direction; an injecting unit configured to inject a reaction gas into the process space; and an exhausting unit in fluidic communication with the chamber at a plurality of locations along the vertical direction of the chamber and configured to provide a uniform exhausting pressure in the process space along the vertical length of the chamber.

The vertical chamber may further include a plurality of exhaust ducts each in fluidic communication with the process space and provided at a respective one of the plurality of locations along the vertical direction of the chamber, each exhaust duct having a different diameter, wherein the exhausting unit is in fluidic communication with the plurality of exhaust ducts.

The chamber may include an outer tube; an inner tube arranged within the outer tube to define the process space inside the inner tube; and a first partition connected between the inner tube and the outer tube to partition a space between the outer tube and the inner tube into a first exhaust passageway in fluidic communication with the process space at a first location of the plurality of locations along the vertical direction, and a second exhaust passageway in fluidic communication with the process space at a second location of the plurality of locations along the vertical direction, wherein the exhausting unit is independently in fluidic communication with the first exhaust passageway and the second exhaust passageway.

In some exemplary embodiments, the inner tube may comprise a first slit that connects the first exhaust passageway and the process space; and a second slit that connects the second exhaust passageway and the process space.

### BRIEF DESCRIPTION OF THE DRAWINGS

The above and/or other aspects will be more clearly understood from the following detailed description of exemplary embodiments taken in conjunction with the accompanying drawings, in which:

FIG. 1 is a cross-sectional view illustrating a vertical furnace in accordance with exemplary embodiments;

FIG. 2 is an exploded perspective view illustrating a chamber of the vertical furnace of FIG. 1;

FIG. 3 is a perspective view illustrating a first exhaust passageway of the chamber of FIG. 2;

FIG. 4 is a perspective view illustrating a second exhaust passageway of the chamber of FIG. 2;

FIG. 5 is a perspective view illustrating a third exhaust passageway of the chamber of FIG. 2;

FIG. 6 is a cross-sectional view illustrating a vertical furnace in accordance with exemplary embodiments; and

FIG. 7 is a side view illustrating exhaust ducts of the vertical furnace of FIG. 6.

### DETAILED DESCRIPTION

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout the drawings.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a “first” element, component, region, layer or section discussed below could be termed a “second” element, component, region, layer or section without departing from the teachings of the present invention.

Spatially relative terms, such as “beneath,” “below,” “lower,” “above,” “upper,” “right,” “left” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

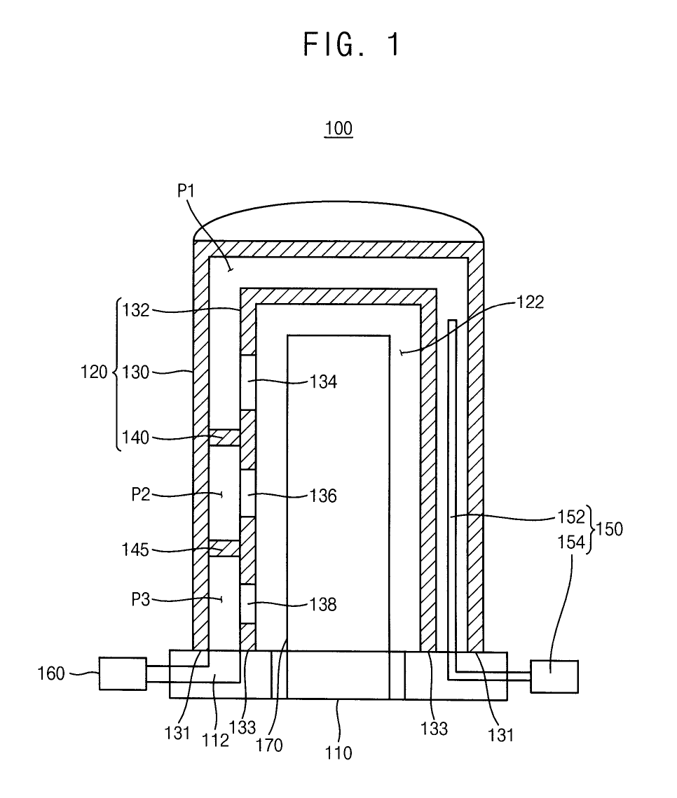

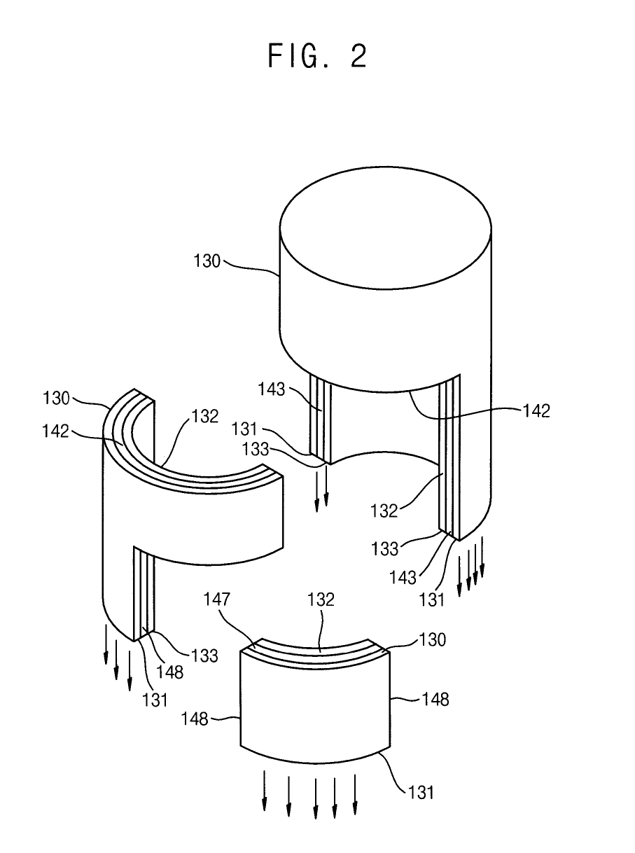

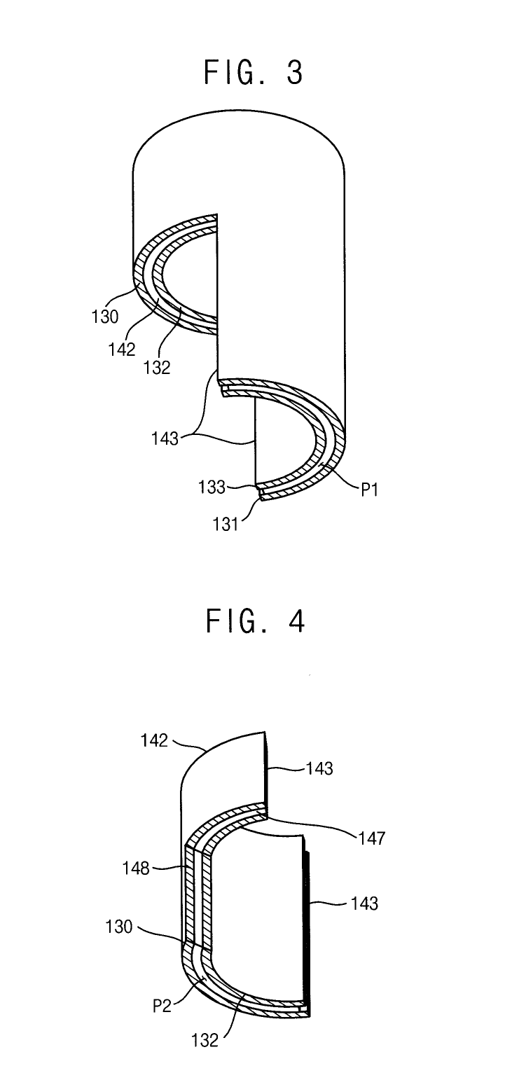

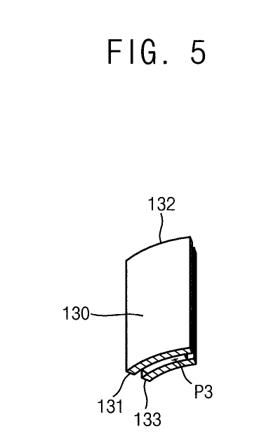

FIG. 1 is a cross-sectional view illustrating a vertical furnace in accordance with an exemplary embodiment, FIG. 2 is an exploded perspective view illustrating a chamber of the vertical furnace of FIG. 1, FIG. 3 is a perspective view illustrating a first exhaust passageway of the chamber of FIG. 2, FIG. 4 is a perspective view illustrating a second exhaust passageway of the chamber of FIG. 2, and FIG. 5 is a perspective view illustrating a third exhaust passageway of the chamber of FIG. 2.

Referring to FIGS. 1 to 5, a vertical furnace 100 of this exemplary embodiment may include a mount block 110, a chamber 120, an injecting unit 150, a boat 170 and an exhausting unit 160.

The mount block 110 may be configured to support the chamber 120, the injecting unit 150 and the exhausting unit 160. The chamber 120 may be mounted on an upper surface of the mount block 110. The injecting unit 150 may be mounted on one side of the mount block 110. The exhausting unit 160 may be mounted on another side of the mount block 110 opposite to the side on which the injecting unit 150 is mounted. For example, in FIG. 1, the injecting unit 150 is shown mounted on a right portion of the mount block 110, and the exhausting unit 160 is shown mounted on a left portion of the mount block 110. The mount block 110 may have a main exhaust passageway 112 in fluidic communication with the exhausting unit 160.

The boat 170 may be configured to receive a plurality of semiconductor substrates. The semiconductor substrates may be horizontally inserted into slots formed on both side surfaces of the boat 170. The boat 170 may be lifted through a bottom surface of the mount block 110.

The injecting unit 150 may include a reaction gas source 154 and a nozzle 152. The nozzle 152 may be vertically arranged in the chamber 120. For example, the nozzle 152 may extend upward from the upper surface of the mount block 110, as shown in FIG. 1. The nozzle 152 may inject a reaction gas into the chamber 120.

The chamber 120 may have a process space 122 configured to receive the boat 170. Thus, the boat 170 may be loaded into the chamber 120. The boat 170 may be positioned in the process space 122. In some exemplary embodiments, the chamber 120 may include an outer tube 130, an inner tube 132, a first partition 140 and a second partition 145.

The outer tube 130 may have a lower end 131 fixed to the upper surface of the mount block 110. The inner tube 132 may be arranged inside the outer tube 130. The inner tube 132 may have a lower end 133 fixed to the upper surface of the mount block 110. Therefore, an exhaust passageway may be formed between the inner tube 132 and the outer tube 130. The exhaust passageway may be in fluidic communication with the main exhaust passageway 112.

The first partition 140 may be connected between the outer tube 130 and the inner tube 132 to form a first exhaust passageway P1 and a second exhaust passageway P2, such that the first exhaust passageway P1 and the second exhaust passageway P2 are isolated from each other. The second partition 145 may be connected between the outer tube 130 and the inner tube 132 to form a third exhaust passageway P3, such that the third exhaust passageway P3 is isolated from the second exhaust passageway P2 and from the first exhaust passageway P1. Thus, the outer tube 130 and the inner tube 132 may have an integral structure connected with each other via the first partition 140 and the second partition 145. As shown in FIG. 2, the first exhaust passageway P1, the second exhaust passageway P2 and the third exhaust passageway P3 may be independently connected to the main exhaust passageway 112. In other words, the sides with the downward-pointing arrows in FIG. 2 are connected to the mount block 110.

Referring to FIG. 2, in some exemplary embodiments, the first partition 140 may include a first horizontal wall 142 and a first vertical wall 143. The first horizontal wall 142 may be connected horizontally between a middle portion in a vertical direction of an inner surface of the outer tube 130 and a middle portion in a vertical direction of an outer surface of the inner tube 132. The first horizontal wall 142 may have a semi-circular shape. The first vertical wall 143 may extend from each end of the first horizontal wall 142 to lower ends 131, 133 of the outer tube 130 and the inner tube 132. As shown in FIG. 3, the first exhaust passageway P1 may be defined by the inner surface of the outer tube 130, the outer surface of the inner tube 132, an upper surface of the first horizontal wall 142 and an outer surface of the first vertical wall 143.

In some exemplary embodiments, the second partition 145 may include a second horizontal wall 147 and a second vertical wall 148. The second horizontal wall 147 may be connected horizontally between a lower portion in the vertical direction of the inner surface of the outer tube 130 and a lower portion in a vertical direction of the outer surface of the inner tube 132. The second horizontal wall 147 may have a quarter-circular shape. The second vertical wall 148 may extend from each end of the second horizontal wall 147 to the lower ends 131, 133 of the outer tube 130 and the inner tube 132. As shown in FIG. 4, the second exhaust passageway P2 may be defined by the inner surface of the outer tube 130, the outer surface of the inner tube 132, a lower surface of the first horizontal wall 142, an inner surface of the first vertical wall 143, an upper surface of the second horizontal wall 147 and an outer surface of the second vertical wall 148. Further, the third exhaust passageway P3 may be defined by the inner surface of the outer tube 130, the outer surface of the inner tube 132, a lower surface of the second horizontal wall 147 and an inner surface of the second vertical wall 148.

In some exemplary embodiments, the shapes of the first horizontal wall 142 and the second horizontal wall 147 may be different than the above-mentioned specific shapes. Because volumes of the first exhaust passageway P1 and the second exhaust passageway P2 and the third exhaust passageway P3 may be determined in accordance with the shapes of the first horizontal wall 142 and the second horizontal wall 147, the shapes of the first horizontal wall 142 and the second horizontal wall 147 may vary in accordance with a condition that the reaction gas injected from the injecting unit 150 may uniformly flow in the process space 122 of the chamber 120 in a horizontal direction.

Returning to FIG. 1, the first exhaust passageway P1 may be in fluidic communication with the process space 122 through a first slit 134 in the inner tube 132. The second exhaust passageway P2 may be in fluidic communication with the process space 122 through a second slit 136 in the inner tube 132. The third exhaust passageway P3 may be in fluidic communication with the process space 122 through a third slit 138 in the inner tube 132. In some exemplary embodiments, the first slit 134, the second slit 136 and the third slit 138 may be vertically formed in the inner tube 132. As shown in FIG. 1, the first slit 134 may have a length longer than a length of the second slit 136. The length of the second slit 136 may be longer than a length of the third slit 138. Thus, when the first slit 134, the second slit 136 and the third slit 138 have substantially the same width, the first slit 134 may have the largest area and the third slit 138 may have the smallest area.

The exhausting unit 160 may provide the first exhaust passageway P1 with a first exhaust pressure. The exhausting unit 160 may provide the second exhaust passageway P2 with a second exhaust pressure. The exhausting unit 160 may provide the third exhaust passageway P3 with a third exhaust pressure. A first distance from the exhausting unit 160 to the first slit 134 may be longer than a second distance from the exhausting unit 160 to the second slit 136. The second distance may be longer than a third distance from the exhausting unit 160 to the third slit 138.

If the first exhaust passageway P1, the second exhaust passageway P2 and the third exhaust passageway P3 have substantially the same volume, the third exhaust pressure may be lowest and the first exhaust pressure may be highest of the three exhaust pressures because the third exhaust passageway P3 is positioned nearest to the exhausting unit 160. Thus, a speed of the reaction gas in a lower portion of the process space 122 may be relatively more rapid than a speed of the reaction gas in an upper portion of the process space 122.

In contrast, in exemplary embodiments, when the first exhaust passageway P1 has the largest volume and the third exhaust passageway P3 has the smallest volume of the three passageways, the first exhaust pressure, the second exhaust pressure and the third exhaust pressure may be substantially equal to each other. Thus, a uniform exhaust pressure may be applied to the process space 122 so that the reaction gas may be horizontally moved in all of the process space 122 at a uniform speed. As a result, layers on the semiconductor substrates may have improved thickness uniformity.

Further, in other exemplary embodiments, the exhausting unit 160 may be positioned nearest to the first exhaust passageway P1, and the exhaust unit may be positioned farthest to the third exhaust passageway P3 among the three passageways. Thus, the exhaust pressure provided to the first exhaust passageway P1 may be relatively lower than the exhaust pressure provided to the third exhaust passageway P3. As a result, the uniform exhaust pressure may be provided to the first exhaust passageway P1, the second exhaust passageway P2 and the third exhaust passageway P3.

In some exemplary embodiments, the exhaust passageway between the inner tube 132 and the outer tube 130 may be divided into the three exhaust passageways having different volumes. Alternatively, in other exemplary embodiments, the exhaust passageway between the inner tube 132 and the outer tube 130 may be divided into two exhaust passageways having different volumes, or at least four exhaust passageways having different volumes. That is, while the exemplary embodiment shown in FIGS. 1 and 2 includes three exhaust passageways, the number of passageways is not particularly limited, and the number of passageways may be two, or four or more without departing from the spirit of the present inventive concept.

According to some exemplary embodiments, for example an exemplary embodiment having two passageways, the first exhaust passageway of the chamber far from the exhausting unit may have a volume larger than the volume of the second exhaust passageway of the chamber adjacent to the exhausting unit. Thus, the exhausting pressure may be uniformly provided to the process space so that the reaction gas may also be uniformly applied to the substrates.

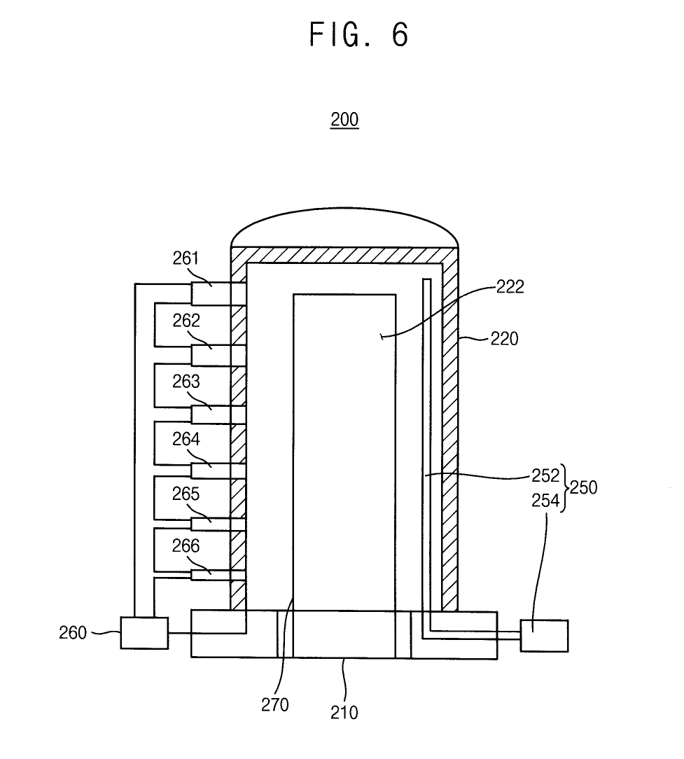

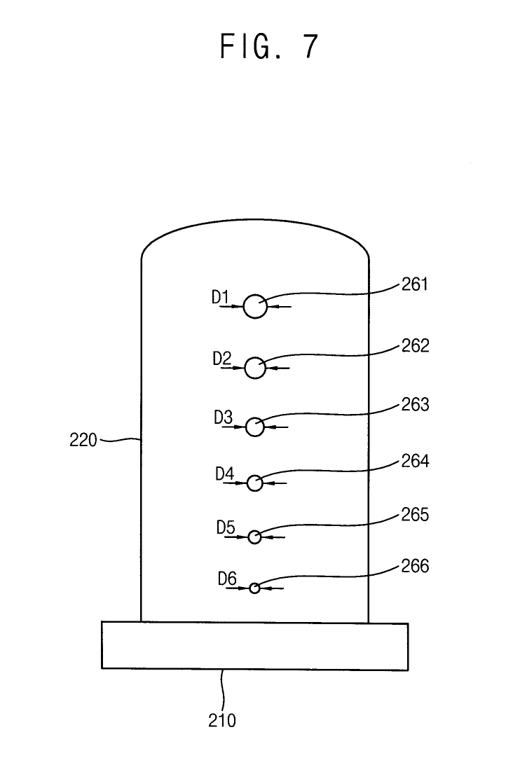

FIG. 6 is a cross-sectional view illustrating a vertical furnace in accordance with another exemplary embodiment, and FIG. 7 is a side view illustrating exhaust ducts of the vertical furnace in FIG. 6.

Referring to FIGS. 6 and 7, a vertical furnace 200 of this exemplary embodiment may include a mount block 210, a chamber 220, an injecting unit 250, a boat 270 and an exhausting unit 260.

The mount block 210 may be configured to support the chamber 220, the injecting unit 250 and the exhausting unit 260. The chamber 220 may be mounted on an upper surface of the mount block 210. The injecting unit 250 may be mounted on one side of the mount block 210. The exhausting unit 260 may be mounted on the other side of the mount block 210 from the one side on which the injecting unit 250 is mounted. For example, in FIG. 6, the injecting unit 250 is shown mounted on a right portion of the mount block 210, and the exhausting unit 260 is shown mounted on a left portion of the mount block 210.

The boat 270 may be configured to receive a plurality of semiconductor substrates. The semiconductor substrates may be horizontally inserted into slots formed on both side surfaces of the boat 270. The boat 270 may be lifted through a bottom surface of the mount block 210.

The injecting unit 250 may include a reaction gas source 254 and a nozzle 252. The nozzle 252 may be vertically arranged in the chamber 220. For example, the nozzle 252 may extend upward from the upper surface of the mount block 210, as shown in FIG. 6. The nozzle 252 may inject a reaction gas into the chamber 220.

The chamber 220 may have a process space 222 configured to receive the boat 270. Thus, the boat 270 may be loaded into the chamber 220. The boat 270 may be positioned in the process space 222. In some exemplary embodiments, the chamber 220 may include only an outer tube. Thus, in some exemplary embodiments, the inner tube may be omitted from the chamber 220.

A first exhaust duct 261, a second exhaust ducts 262, a third exhaust duct 263, a fourth exhaust duct 264, a fifth exhaust duct 265, and a sixth exhaust duct 266 may be vertically arranged in a first exhaust passageway, a second exhaust passageway, a third exhaust passageway, a fourth exhaust passageway, a fifth exhaust passageway, and a sixth exhaust passageway, respectively, formed in an outer surface of the chamber 220. The first to sixth exhaust ducts 261, 262, 263, 264, 265 and 266 may be in fluidic communication with the first to sixth exhaust passageways in order to be in fluidic communication with the process space 222 of the chamber 220. The first to sixth exhaust ducts 261, 262, 263, 264, 265 and 266 may be connected to the exhausting unit 260.

In some exemplary embodiments, the first exhaust duct 261 may correspond to an uppermost exhaust duct, and the sixth exhaust duct 266 may correspond to a lowermost exhaust duct of the six ducts. The first exhaust duct 261 may have a first diameter D1. The second exhaust duct 262 may have a second diameter D2. The third exhaust duct 263 may have a third diameter D3. The fourth exhaust duct 264 may have a fourth diameter D4. The fifth exhaust duct 265 may have a fifth diameter D5. The sixth exhaust duct 266 may have a sixth diameter D6. The first diameter D1 may be largest and the sixth diameter D6 may be smallest of the six diameters. Thus, the first exhaust duct 261 farthest from the exhausting unit 260 may have the largest diameter D1 and the sixth exhaust duct 266 nearest from the exhausting unit 260 may have the smallest diameter D6 so that a uniform exhaust pressure from the exhausting unit 260 may be supplied to the first to sixth exhaust ducts 261, 262, 263, 264, 265 and 266. Therefore, the uniform exhaust pressure may also be supplied to the process space 222 so that the reaction gas may be uniformly applied to semiconductor substrates. As a result, layers on the semiconductor substrates may have improved thickness uniformity.

In some exemplary embodiments, the vertical furnace 200 may include the six exhaust ducts having different diameters as described above. Alternatively, in other exemplary embodiments, the number of the exhaust ducts having different diameters may be changed in accordance with a condition that the reaction gas may uniformly flow in the process space of the chamber in a horizontal direction.

In some exemplary embodiments, the substrates processed in the vertical furnace may include the semiconductor substrates. Alternatively, in other exemplary embodiments, the substrates may include other substrates such as glass substrates.

According to some exemplary embodiments, the first exhaust passageway of the chamber far from the exhausting unit may have the volume larger than the volume of the second exhaust passageway of the chamber located more adjacent to the exhausting unit. Thus, the exhausting pressure may be uniformly provided to the process space so that the reaction gas may also be uniformly applied to the substrates.

Alternatively, according to other exemplary embodiments, the first exhaust duct farthest from the exhausting unit may have the diameter larger than the diameter of the second exhaust duct located more close to the exhausting unit. Therefore, the exhausting pressure may be uniformly provided to the process space so that layers on the substrates may have improved thickness uniformity.

The foregoing is illustrative of exemplary embodiments and is not to be construed as limiting thereof. Although a few exemplary embodiments have been described, those skilled in the art will readily appreciate that many modifications are possible to the exemplary embodiments without materially departing from the novel teachings and advantages of the present invention. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A vertical furnace comprising:
a chamber comprising a process space configured to receive substrates, a first exhaust passageway in fluidic communication with the process space, and a second exhaust passageway in fluidic communication with the process space and isolated from the first exhaust passageway;
an injecting unit configured to inject a reaction gas into the process space; and
an exhausting unit in fluidic communication with the first exhaust passageway and the second exhaust passageway and configured to provide the first exhaust passageway and the second exhaust passageway with an exhausting pressure.

2. The vertical furnace of claim 1, wherein the first exhaust passageway has a volume that is larger than a volume of the second exhaust passageway.

3. The vertical furnace of claim 2, wherein a distance from a first connection between the first exhaust passageway and the process space to the exhausting unit is longer than a distance from a second connection between the second exhaust passageway and the process space to the exhausting unit.

4. The vertical furnace of claim 1, wherein the chamber comprises:
an outer tube;
an inner tube arranged within the outer tube to define the process space inside the inner tube; and
a first partition connected between the inner tube and the outer tube to partition a space between the outer tube and the inner tube into the first exhaust passageway and the second exhaust passageway, and to isolate the first exhaust passageway from the second exhaust passageway.

5. The vertical furnace of claim 4, wherein the first partition comprises:
a first horizontal wall connected between an outer surface of the inner tube and an inner surface of the outer tube; and
a first vertical wall that extends from each end of the first horizontal wall to lower ends of the inner tube and the outer tube, respectively.

6. The vertical furnace of claim 4, wherein the inner tube has:
a first slit that connects the first exhaust passageway and the process space; and
a second slit that connects the second exhaust passageway and the process space.

7. The vertical furnace of claim 6, wherein the first slit has an area larger than an area of the second slit.

8. The vertical furnace of claim 1, wherein the chamber further comprises a third exhaust passageway in fluidic communication with the process space and isolated from the first exhaust passageway and from the second exhaust passageway.

9. The vertical furnace of claim 2, wherein the chamber further comprises a third exhaust passageway in fluidic communication with the process space and isolated from the first exhaust passageway and from the second exhaust passageway, and
wherein the third exhaust passageway has a volume smaller than the volume of the second exhaust passageway.

10. The vertical furnace of claim 8, wherein the chamber comprises:
an outer tube;
an inner tube arranged within the outer tube to define the process space inside the inner tube;
a first partition connected between the inner tube and the outer tube to partition a space between the outer tube and the inner tube into the first exhaust passageway and the second exhaust passageway, and to isolate the first exhaust passageway from the second exhaust passageway; and
a second partition connected between the inner tube and the outer tube to partition the space between the outer tube and the inner tube into the second exhaust passageway and the third exhaust passageway, and to isolate the third exhaust passageway from the second exhaust passageway.

11. The vertical furnace of claim 10, wherein the inner tube has:
a first slit that connects the first exhaust passageway and the process space;
a second slit that connects the second exhaust passageway and the process space; and
a third slit that connects the third exhaust passageway and the process space.

12. The vertical furnace of claim 11, wherein the third slit has an area smaller than areas of the first slit and the second slit.

13. The vertical furnace of claim 1, further comprising a mount block arranged under the chamber, the mount block having a main exhaust passageway that connects the first exhaust passageway, the second exhaust passageway, and the exhausting unit.

14. A vertical furnace comprising:
a chamber comprising a process space configured to receive substrates;
an injecting unit configured to inject a reaction gas into the process space;
first and second exhaust ducts connected to respective openings in a side surface of the chamber so as to be in fluidic communication with the process space, the first and second exhaust ducts having different diameters; and
an exhausting unit in fluidic communication with the first and second exhaust ducts and configured to provide the first and second exhaust ducts with an exhausting pressure.

15. The vertical furnace of claim 14, wherein a distance from the first exhaust duct to the exhausting unit is longer than a distance from the second exhaust duct to the exhausting unit, and the first exhaust duct has a diameter larger than a diameter of the second exhaust duct.

16. The vertical furnace of claim 1, wherein:
the first exhaust passageway comprises an opening formed in a side surface of the chamber, and
the second exhaust passageway comprises an opening formed in the side surface of the chamber,
the vertical furnace further comprising:
first and second exhaust ducts in fluidic communication with the first exhaust passageway and the second exhaust passageway, respectively, the first and second exhaust ducts having different diameters; and
an exhausting unit in fluidic communication with the first and second exhaust ducts and configured to provide the first and second exhaust ducts with an exhausting pressure.

17. A vertical furnace comprising:
a chamber comprising a process space configured to receive substrates, the chamber extending in a vertical direction;
an injecting unit configured to inject a reaction gas into the process space; and
an exhausting unit in fluidic communication with the chamber at a plurality of locations along the vertical direction of the chamber and configured to provide a uniform exhausting pressure in the process space along the vertical direction of the chamber.

18. The vertical furnace of claim 17, further comprising:
a plurality of exhaust ducts in fluidic communication with the process space and provided at a respective one of the plurality of locations along the vertical direction of the chamber, each exhaust duct having a different diameter,
wherein the exhausting unit is in fluidic communication with the plurality of exhaust ducts.

19. The vertical furnace of claim 17, wherein the chamber comprises:
an outer tube;
an inner tube arranged within the outer tube to define the process space inside the inner tube; and
a first partition connected between the inner tube and the outer tube to partition a space between the outer tube and the inner tube into a first exhaust passageway in fluidic communication with the process space at a first location of the plurality of locations along the vertical direction, and a second exhaust passageway in fluidic communication with the process space at a second location of the plurality of locations along the vertical direction,
wherein the exhausting unit is independently in fluidic communication with the first exhaust passageway and the second exhaust passageway.

20. The vertical furnace of claim 19, wherein the inner tube comprises:
a first slit that connects the first exhaust passageway and the process space; and
a second slit that connects the second exhaust passageway and the process space.
